(19) United States
(12) Patent Application Publication
(10) Pub. No.: US 2015/0105910 A1
(43) Pub. Date: Apr. 16, 2015

(54) Server System with Fan controllers

(71) Applicants: INVENTEC CORPORATION, TAIPEI CITY (TW); INVENTEC (PUDONG) TECHNOLOGY CORPORATION, SHANGHAI (CN)

(72) Inventor: Xiao-Bing ZOU, SHANGHAI (CN)

(73) Assignees: INVENTEC CORPORATION, TAIPEI CITY (TW); INVENTEC (PUDONG) TECHNOLOGY CORPORATION, Shanghai (CN)

(21) Appl. No.: 14/149,837

(22) Filed: Jan. 8, 2014

(30) Foreign Application Priority Data
Oct. 12, 2013 (CN) 201310475932.7
Oct. 12, 2013 (CN) 201310548604.5

(51) Int. Cl. H05K 7/20

(52) U.S. Cl. CPC H05K 7/20836
USPC 700/275

(57) ABSTRACT

A server system comprises a fan backplate, a server array, a substrate, a first fan controller and a second fan controller. The fan backplate couples with fans. The server array includes calculation nodes. The substrate has a multiplexer. The calculation nodes couple with the multiplexer. The first fan controller and the second fan controller couple with the calculation nodes through the multiplexer. A fan control signal is generated according to the real-time temperature of the calculation nodes to control the fans. The first fan controller and the second fan controller form a redundancy system.

### RELATED APPLICATIONS

This application claims priority to Chinese Application Serial Number 201310475932.7, filed Oct. 12, 2013, and Chinese Application Serial Number 201310548604.5, filed Oct. 12, 2013, which are herein incorporated by reference.

### BACKGROUND

1. Field of Invention

The invention relates to a server system, and particularly relates to a server system with fan controllers.

2. Description of Related Art

Thermal control is important to keep a stable server. Typically, a server includes a fan to perform the thermal control. Therefore, when multiple servers are grouped together to perform calculation work, it is required for fans equal to the servers in amount to realize thermal control. Particularly, in a Microserver array usage, there are twelve CPU boards in a 2U server cabinet, in which each CPU board includes four system-on-chips respectively working as a server. To perform the thermal control in the server cabinet, a fan control system is typically used to control the fans. However, if the fan control system fails to properly work, the fans can no longer function to thermally control the server cabinet, which causes damage for the server.

Therefore, a server system with fan controllers can solve the above problem is needed.

### SUMMARY

Accordingly, the present invention provides a server system with fan controllers to improve the reliability of thermal control.

An aspect of the invention provides a server system comprising a fan backplate, a server array, a substrate, a first fan controller and a second fan controller. The fan backplate couples with fans. The server array includes calculation nodes. The substrate has a multiplexer. The calculation nodes couple with the multiplexer. The first fan controller and the second fan controller couple with the calculation nodes through the multiplexer. A fan control signal is generated according to the real-time temperature of the calculation nodes to control the fans. The first fan controller and the second fan controller form a redundancy system.

In an embodiment, a power supply module transfers power to the fans through branch power lines respectively. Each of the first fan controller and the second fan controller further comprises a control unit, a current monitor, current sampling units and switches. The current monitor couples with the control unit. The current sampling units and switches are disposed on the branch power lines respectively. The current sampling units couple with the current monitor. The switches couple with the control unit. The control unit is able to control each of the switches' opening and closing and the current monitors are used for sampling current signals flowing through the current sampling units respectively. When the current monitor monitors one of the current signals being over a threshold value, the current monitor issues an over-current signal to the control unit to turn off the corresponding switch to cut off the power supplied to the corresponding fan by the power supply module.

In an embodiment, the switches are transistors, the source electrodes and the drain electrodes of the transistors are coupled to the branch power lines respectively and the gate electrodes of the transistors are coupled to the control unit.

In an embodiment, the fans correspond to printed circuit boards respectively. Indicator lights are disposed on the printed circuit boards respectively. When one of the fans is broken, the control unit generates a failure signal to turn on a corresponding indicator light.

In an embodiment, the control unit further couples with a thermal unit of each of the calculation nodes, and the control unit generates the fan control signal to control the fans according to a real-time temperature of the thermal unit. The control unit has a fan control table, the fan control table records the relationship between temperatures of the thermal unit and set rotation speeds of fans, wherein the control unit gets a set rotation speed according to the real-time temperature of the thermal unit from the fan control table, and the control unit generates the fan control signal according to the set rotation speed. The fan backplate further comprises a first connector and a second connector, the fans receive the fan control signal through the first connector and the fans couple with the power supply module through the second connector

In an embodiment, the fan backplate provides rotation speed feedback signals to the control unit, the control unit determines actual rotation speeds of the fans according to the rotation speed feedback signals, wherein when the actual rotation speed of a fan is not equal to its corresponding set rotation speed, the fan is determined to be broken. When the control unit still receives the rotation speed feedback signals after the control unit turns off the switches, the fan controller is determined to be broken.

In an embodiment, the control unit of the fan controller further performs a self detection process, and when the control unit of the fan controller can not read the fan control table, the fan controller is determined to be broken.

In an embodiment, the control unit of the fan controller further performs a self detection process, when the control unit of the fan controller can not read the fan control table, the fan controller is determined to be broken.

In an embodiment, the control unit of the first fan controller couples with the second fan controller through a serial general purpose input/output bus.

In an embodiment, when the second fan controller can not get any information from the first fan controller through the serial general purpose input/output bus, the first fan controller is determined to be broken and the second fan controller controls the fans instead of the first fan controller.

In an embodiment, the first fan controller is able to inform the second fan controller through the serial general purpose input/output bus to control the fans.

In view of the above, the server system includes a backup fan controller. When one of the fan controllers is broken, the backup fan controller is triggered to control the fans. Therefore, the thermal damage for the server system is prevented. Moreover, a hot-plugging method is used to replace the fan controllers or the fans. Therefore, it is not necessary to power off the server system to replace the fan controllers or fans.

### BRIEF DESCRIPTION OF THE DRAWINGS

FIG. 1 illustrates a schematic view of a server system according to an embodiment of the invention.

FIG. 2 illustrates a schematic view of a first fan controller according to an embodiment of the invention.

### DETAILED DESCRIPTION

Specific embodiments of the invention are described in details as follows with reference to the accompanying drawings, wherein throughout the following description and drawings, the same reference numerals refer to the same or similar elements and are omitted when the same or similar elements are stated repeatedly.

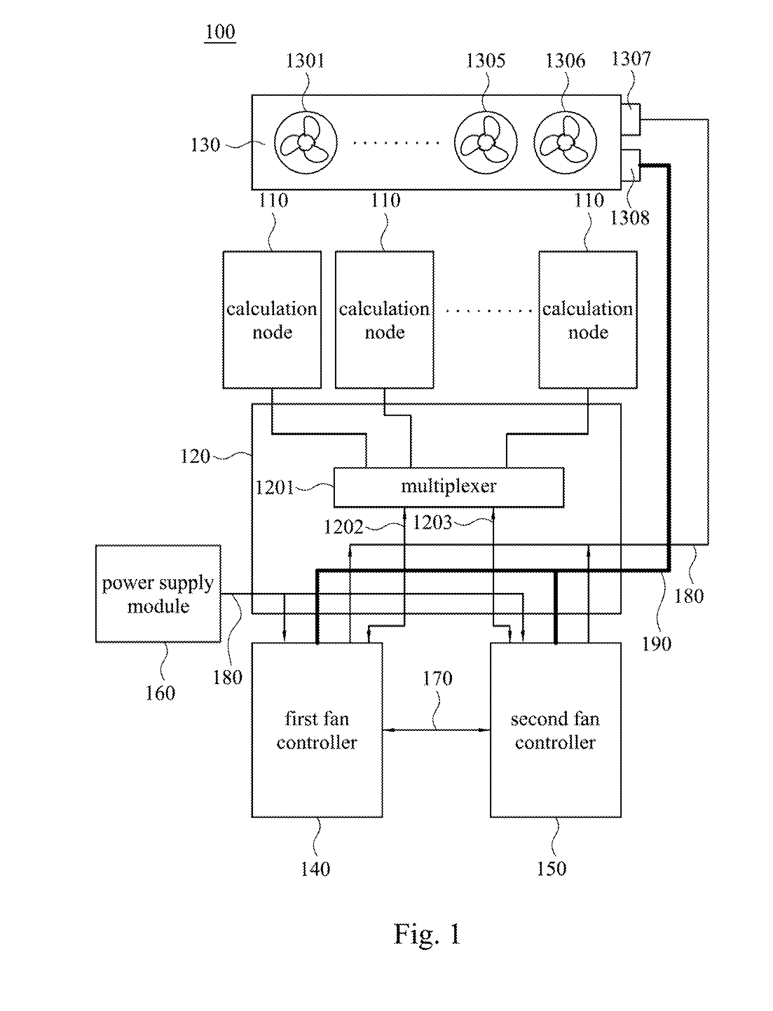

FIG. 1 illustrates a schematic view of a server system according to an embodiment of the invention. A server system 100 of the invention includes a server array with calculation nodes 110, a substrate 120, a fan backplate 130, a first fan controller 140, a second fan controller 150 and a power supply module 160. The calculation nodes 110 couple with the substrate 120 respectively. The substrate 120 selects one of the calculation nodes 110 through the multiplexer 1201. The substrate communicates with the selected calculation node to get its data. The data is transferred to the first fan controller 140 and the second fan controller 150 through the I2C bus 1202 and the I2C bus 1203 respectively. Fans 1301-1306 are disposed on and coupled to the fan backplate 130. The power supply module 160 supplies voltage signal to the first fan controller 140 and the second fan controller 150 through the power line 180. Then, the voltage signal is transferred to the fans 1301-1306 on the fan backplate 130 by the first fan controller 140 and the second fan controller 150 through the power line 180. For example, a voltage signal with 12 volts is transferred to the fans 1301-1306 on the fan backplate 130. In an embodiment, the first fan controller 140 or the second fan controller 150 generates a control signal according to the data of one of the calculation nodes 110 selected by the multiplexer 1201 in the substrate 120. This control signal controls the rotation speed of the fans 1301-1306 on the fan backplate 130 through a signal line 190. The power line 180 is connected to the connector 1307 disposed on the fan backplate 130. The signal line 190 is connected to the connector 1308 disposed on the fan backplate 130. Because no other electrical devices are disposed on the fan backplate 130, the reliability of the fan backplate 130 is much improved.

In this embodiment, the first fan controller 140 communicates with the second fan controller 150 through a serial general purpose input/output, SGPIO, bus 170. The first fan controller 140 and the second fan controller 150 do not be operated at the same time. The first fan controller 140 and the second fan controller 150 form a redundancy system, so that the first fan controller 140 and the second fan controller 150 are mutual redundant. When the first fan controller 140 is used to control the rotation speed of the fans 1301-1306, the second fan controller 150 is in a standby state. In contrast, when the second fan controller 150 is used to control the rotation speed of the fans 1301-1306, the first fan controller 140 is in a standby state. In other word, the server system includes a backup fan controller. When one of the two fan controllers is broken, another fan controller is triggered to control the fans 1301-1306. Therefore, the thermal damage for the server system is prevented. On the other hand, a hot-plugging method is used to replace the first fan controller 140 and the second fan controller 150 in the server system. Therefore, it is not necessary to power off the server system to replace the fan controllers.

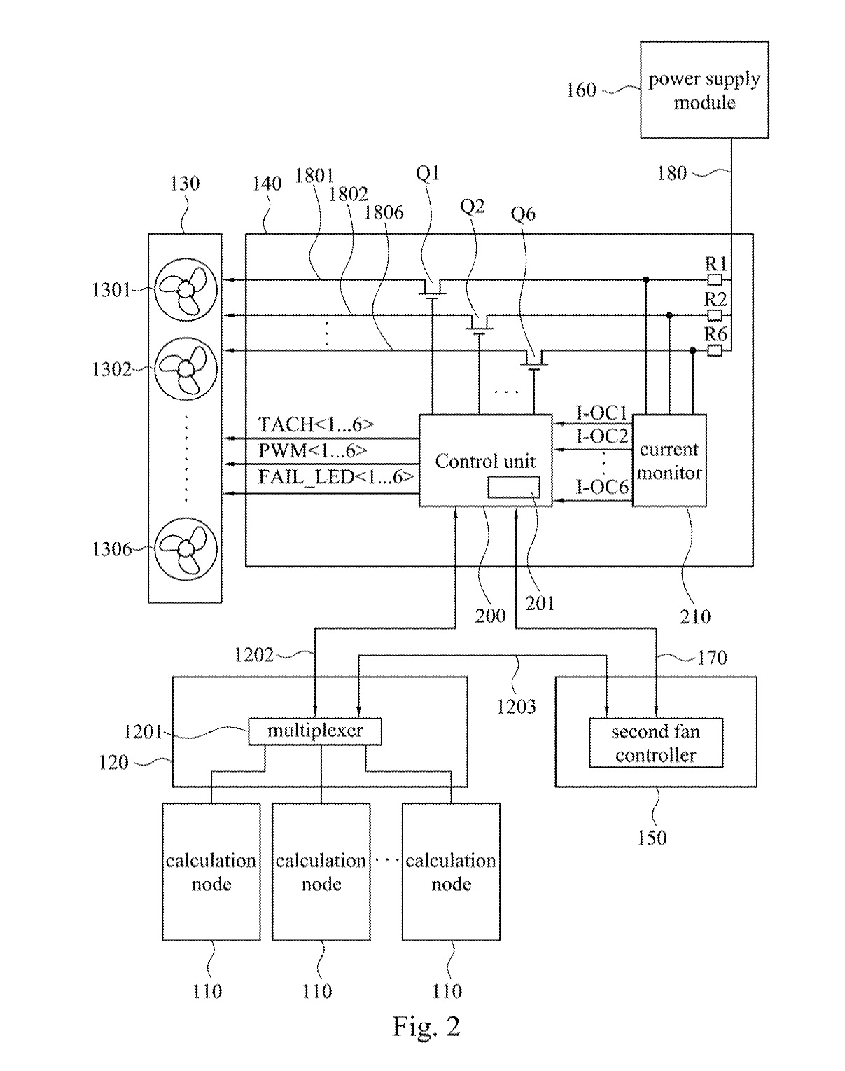

FIG. 2 illustrates a schematic view of a first controller according to an embodiment of the invention. The first fan controller 140 and the second fan controller 150 have a same structure. In this embodiment, the first controller 140 is used to control fans 1301-1306 on the fan backplate 130. The first fan controller 140 comprises a control unit 200, a current monitor 210 and a power supply module 160. Because the first fan controller controls fans 1301-1306 at the same time, the power line 180 from the power supply module 160 are separated to six branch power lines 1801-1806 to transfer voltage signal to the fans 1301-1306 respectively. Six current sampling units R1-R6 and six switches Q1-Q6 are disposed on the branch power lines 1801-1806 respectively. Accordingly, after the first fan controller 140 receives the voltage signal from the power supply module 160, the voltage signal is transferred to the fans 1301-1306 through the current sampling units R1-R6 and switches Q1-Q6 respectively. Current sampling units R1-R6 couple with the current monitor 210. Switches Q1-Q6 couple with the control unit 200. The control unit 200 controls the switches Q1-Q6′ opening and closing. The current sampling units R1-R6 sample the current signals in the branch power lines 1801-1806 respectively for the current monitor 210. The current monitor 210 monitors the voltage supplied to the fans 1301-1306 respectively according to the current signals flowing through the current sampling units R1-R6. When the current monitor 210 monitors one of the current signals being over a threshold value, a corresponding over-current signal I_OC1-I_OC6 is issued by the current monitor 210 to the control unit 200 to turn-off the corresponding switch Q1-Q6 to cut off the power supplied to the fan by the power supply module 160. Therefore, over-current damage to fans 1301-1306 is prevented. On the other hand, when one of the fans 1301-1306 is broken because of over-current damage, the control unit 200 generates a failure signal FAIL_LED to turn on a corresponding indicator light, such as a LED, to inform the operator the one of the fans 1301-1306 is broken. In this embodiment, a hot plugging method is used to replace the broken fan. The current sampling units R1-R6 are resistors. The switches Q1˜Q6 are transistors, such as P-type transistors. The source electrodes and the drain electrodes of the transistors are coupled to the branch power lines 1801-1806 respectively. The gate electrodes of the transistors are coupled to the control unit 200. Printed circuit boards are embedded in shells of fans 1301-1306 respectively. LEDs are disposed on the printed circuit boards. When a fan is broken, a corresponding LED is turned on to inform the operator.

The control unit 200 couples with the multiplexer 1201 in the substrate 120 through the I2C bus 1202 to communicate with the calculation nodes 110. The control unit 200 gets temperature data in real time of thermal units in the calculation nodes 110. According to the real time temperature data, the control unit 200 gathers fan control signals PWM <1 . . . 6> from a fan control table. The fan control table is stored in a memory unit 201 to record the relationship between the temperatures and the rotation speeds. Therefore, each fan control signal PWM<1 . . . 6> can control a fan to rotate in a set rotation speed. Accordingly, the fan control signals PWM <1 . . . 6> are transferred to the fans 1301-1306 from the control unit 200 to control the fans 1301-1306 to rotate according to the set rotation speeds. On the other hand, fan backplate 130 provides rotation speed feedback signals TACH<1 . . . 6> to the control unit 200. According to the rotation speed feedback signals TACH<1 . . . 6>, the control unit 200 can know the actual rotation speeds of fans 1301-1306. In other words, when the rotation speed feedback signals TACH<1 . . . 6> indicate that the actual rotation speeds of some fans are not equal to the set rotation speeds, the control unit 200 can determine that these fans are broken. Then, the failure signals FAIL_LED are issued by the control unit 200 to turn on corresponding LEDs to inform the operator the fans are broken. At the same time, the corresponding switches Q1-Q6 are turned off to cut off the power supply module 160 to supply power to the fans. The failure signals FAIL_LED and the fan control signals PWM <1 . . . 6> are transferred to the control unit 200 through the signal line 190. The fan control signals PWM <1 . . . 6> are transferred to the fan backplate 130 through the signal line 190.

Moreover, according to the rotation speed feedback signals TACH<1 . . . 6> of the fans 1301-1306, the state of the first fan controller 140 can be determined. For example, the control unit 200 issues a control signal to turn off the switch Q1. However, the rotation speed feedback signals TACH<1> of the fan 1301 indicates that the fan 1301 is still in a rotation state. In other words, the switch Q1 does not be turned off. This case means that the control unit 200 or the switch Q1 is broken. The first controller 140 is in an abnormally operation state. Moreover, the control unit 200 also can perform a self-detection process. When at least one of switches Q1-Q6 is out of the control unit 200′ control, the fan controller 140 is determined to be broken. When the control unit 200 can not read the fan control table in a memory unit 201, the control unit 200 is determined to be broken. That is, the first controller 140 is in an abnormal operation state. At this time, the first controller 140 informs the abnormal operation state to the second fan controller 150 through the SGPIO bus 170. Then, the second fan controller 150 gets the right to control the fans 1301-1306. In other words, in this case, the first controller 140 actively informs the second fan controller 150 to get the control right of the fans 1301-1306. In another embodiment, the first controller 140 and the second controller 150 are synchronized through the SGPIO bus 170. Therefore, when the second controller 150 can not get any synchronization signal from the first fan controller 140 through the SGPIO bus 170 in an acquiring, the first fan controller is determined to be broken. Then, the second fan controller 150 gets the right to control the fans 1301-1306.

In view of the above, the server system includes a backup fan controller. When one of the fan controllers is broken, the backup fan controller is triggered to control the fans. Therefore, the thermal damage for the server system is prevented. Moreover, each fan is monitored independently by the current monitor. Therefore, when an over current event happens in a fan, the power supplied to this fan is cut off in real time. At this time, the other fans keep in work. Such fan structure can prevent the thermal damage being spread. On the other hand, a hot-plugging method is used to replace the fan controllers or the fans. Therefore, it is not necessary to power off the server system to replace the fan controllers or fans.

Although the invention has been disclosed with reference to the above embodiments, these embodiments are not intended to limit the invention. It will be apparent to those of skills in the art that various modifications and variations can be made without departing from the spirit and scope of the invention. Therefore, the scope of the invention shall be defined by the appended claims.

What is claimed is:

1. A server system, comprising:
a fan backplate coupling with a plurality of fans;
a server array having a plurality of calculation nodes;
a substrate having a multiplexer, wherein the calculation nodes couples with the multiplexer; and
a first fan controller and a second fan controller coupling with the calculation nodes through the multiplexer, wherein a fan control signal is generated according to a real-time temperature of the calculation nodes to control rotation speed of the fans, wherein the first fan controller and the second fan controller form a redundancy system.

2. The server system of claim 1, further comprising a power supply module transferring power to the fans through a plurality of branch power lines respectively, wherein each of the first fan controller and the second fan controller further comprises:
a control unit;
a current monitor coupling with the control unit; and
a plurality of current sampling units and a plurality of switches disposed on the branch power lines respectively, the current sampling units coupled with the current monitor and the switches coupled with the control unit;
wherein the control unit is able to control each of the switches' opening and closing and the current monitors are used for sampling current signals flowing through the current sampling units respectively, and, when the current monitor monitors one of the current signals being over a threshold value, the current monitor issues an over-current signal to the control unit to turn off the corresponding switch to cut off the power supplied to the corresponding fan by the power supply module.

3. The server system of claim 2, wherein the switches are transistors, the source electrodes and the drain electrodes of the transistors are respectively coupled to the branch power lines, and the gate electrodes of the transistors are coupled to the control unit.

4. The server system of claim 2, wherein when one of the fans is broken, the control unit generates a failure signal to turn on a corresponding indicator light.

5. The server system of claim 4, wherein the fans respectively correspond to printed circuit boards, and a plurality of indicator lights are respectively disposed on the printed circuit boards.

6. The server system of claim 2, wherein the control unit further couples with a thermal unit of each of the calculation nodes, and the control unit generates the fan control signal to control the fans according to real-time temperature of the thermal unit.

7. The server system of claim 6, wherein the control unit has a fan control table that records the relationship between temperatures of the thermal units and set rotation speeds of fans, wherein the control unit gets a set rotation speed according to the real-time temperature of the thermal unit from the fan control table, and the control unit generates the fan control signal according to the set rotation speed.

8. The server system of claim 6, wherein the fan backplate further comprises a first connector for receiving the fan control signal through, and a second connector couples with the branch power lines.

9. The server system of claim 2, wherein the fan backplate provides rotation speed feedback signals to the control unit, and the control unit determines actual rotation speeds of the fans according to the rotation speed feedback signals, wherein, when the actual rotation speed of a fan is not equal to its corresponding set rotation speed, the fan is determined to be broken.

10. The server system of claim 9, wherein when the control unit still receives the rotation speed feedback signals after the control unit turns off the switches, the fan controller is determined to be broken.

11. The server system of claim 2, wherein the control unit of the fan controller further performs a self detection process, and when at least one of switches is out of the control unit of the fan controller’ control, the fan controller is determined to be broken.

12. The server system of claim 2, wherein the control unit of the fan controller further performs a self detection process, and when the control unit of the fan controller can not read the fan control table, the fan controller is determined to be broken.

13. The server system of claim 1, wherein the control unit of the first fan controller couples with the second fan controller through a serial general purpose input/output bus.

14. The server system of claim 13, wherein when the second fan controller can not get any information from the first fan controller through the serial general purpose input/output bus, the first fan controller is determined to be broken and the second fan controller controls the fans instead of the first fan controller.

15. The server system of claim 13, wherein the first fan controller is able to inform the second fan controller through the serial general purpose input/output bus to control the fans.
